(19) United States
(12) Patent Application Publication
(10) Pub. No.: US 2005/0118742 A1
(43) Pub. Date: Jun. 2, 2005

(54) Method for reducing the adhesive properties of MEMS and anti-adhesion-coated device

(76) Inventors: Frank Henning, Reutlingen (DE); Lutz Mueller, Aichtal (DE); Holger Hoefer, Sonnenbuehl (DE); Arnd Kaelberer, Schlierbach (DE)

Correspondence Address: KENYON & KENYON, ONE BROADWAY, NEW YORK, NY, 10004, US

(21) Appl. No.: 10/978,018

(22) Filed: Oct. 28, 2004

(30) Foreign Application Priority Data
Jun. 11, 2004 (DE) 10 2004 028 538.1
Nov. 17, 2003 (DE) 103 53 684.1

(51) Int. Cl. H01L 21/00; H01L 27/14; H01L 29/82; H01L 29/84

(52) U.S. Cl. 438/48; 257/414

(57) ABSTRACT

A method provides coating of the surface of a microelectromechanical structure (MEMS) wafer by using an anti-stick layer. The anti-stick material is initially applied to a cap wafer, and in subsequent steps this seeded cap wafer is bonded to the MEMS wafer. The anti-stick material is evaporated and deposited at least on parts of the surfaces of the MEMS wafer.

### FIELD OF THE INVENTION

The present invention relates to microelectromechanical structures and a method for producing a coating layer on such structures.

### BACKGROUND INFORMATION

Movable elements in microelectromechanical structures (MEMS) are able to stick to the fixed structures. As mechanisms for sticking together, among other things, mechanical overload, electrostatic discharge and chemical bonds come into consideration. In the chemical bonds, van der Waals interactions, ionic interactions, covalent bonds or metallic bonds may be determinative. Touching surfaces having high surface energy, such as silicon surfaces having a cover layer of OH groups or having a water film, may demonstrate strong binding forces which are then based on ionic interactions or covalent bonding (after removal of the water) and which hold the two surfaces together.

The sticking described above may be prevented by coating the surfaces, using anti-adhesive layers, so called anti-sticking layers.

The application of the anti-sticking layer from the liquid phase onto the MEMS structures is possible only with difficulty, since capillary forces bond the MEMS during drying. Methods of coating with organic compounds from the gas phase, e.g., chemical vapor deposition (CVD), using silanes are known, for instance, from published German patent document DE 2625448. These coatings passivate the surfaces with a layer having a lower surface energy and cover possible OH groups. Published German patent document DE 19817310 discloses CVD SiO2 layers, metal oxide layers, metal nitride layers and organic coatings as adhesion-reducing protective layers on the surface of the movable MEMS structures.

Reactive, perfluorinated or aromatic silanes are known and commercially available. Such silanes react with the OH groups present on the component surfaces to form thin, firmly-adhering silane layers. The anti-adhesive, hydrophobic, oleophobic and other repellent properties of such layers are known. A coating method for depositing monolayered perfluorinated silanes from the gas phase (CVD), to protect micromechanical components from sticking, is disclosed in published European patent document EP 0845301.

An additional gas phase coating method, to protect micromechanical components from sticking, is disclosed in U.S. Pat. No. 5,694,740. Silicone oils and, among other things, perfluorinated silanes are used.

Yet another gas phase coating method is described in Sakata J., Tsuchiya T., Inoue A., Tokumitsu S., Funabashi H. et al., “Anti-Stiction Silanization Coating . . . Vapor Phase Deposition Process”, Transducers 99, Jul. 6, 1999, Sendai, Japan. In that publication, micromechanical components are furnished with an “anti-stiction layer” by pas phase coating using 1,1,2,2 tetrahydrofluorooctyltrichlorosilane.

A usual method for manufacturing micromechanical components is to produce a plurality of these components together on one wafer, the so-called MEMS wafer, and thereafter to cut them apart. To protect them from environmental influences, microelectromechanical components are encapsulated. A usual method of encapsulation is to apply a silicon cap to the microelectromechanical component, and to bond it to it, using the sealing glass bonding process. Just the same as the components themselves, the caps too may be produced on a wafer, the so-called cap wafer, and thereafter be cut apart. Finally, a process is also known in which the encapsulation of the component is performed by bonding onto each other the entire MEMS wafer and the entire cap wafer. Subsequently to that, the encapsulated components are then cut apart.

### SUMMARY OF THE INVENTION

The present invention provides a method for manufacturing an anti-adhesive layer on a surface of a MEMS wafer. In this context, the surface is exposed to coating of the gas phase of an anti-adhesive active agent.

In accordance with the present invention, the anti-stiction media are not applied directly to the functional wafer or MEMS wafer, but are applied, in the first process step, to a cap wafer. In subsequent process steps, this “seeded” cap wafer is durably bonded to the functional sensor wafer, i.e. the MEMS wafer. During this procedure, or later, the anti-stiction medium is evaporated, and deposited at least on parts of the surfaces of the MEMS wafer. Thereby the adhesion of the movable elements is prevented. However, in this context, no separate coating step is required for the MEMS wafer.

The method according to the present invention has the advantage of being able to be carried out particularly cost-effectively, and also of having the capability of being used to coat whole batches of wafers (of having batch capability). A further advantage is that one may use production equipment that is already in existence. This method is able to minimize or prevent contamination risks to other products (cross contamination) by anti-stiction media. The device according to the present invention is able to be produced in a particularly cost-effective manner.

It is advantageous here that the active agent is first applied to a cap wafer and the cap wafer is bonded to the MEMS wafer. During this or a subsequent process step, the active agent is evaporated and the surface of the MEMS wafer is coated.

Furthermore, it is of advantage that the cap wafer is bonded to the MEMS wafer with the aid of a sealing glass paste. The sealing glass paste closes off the cavity, the cap wafer and the MEMS wafer hermetically in a limiting way from the environment, and holds the evaporated anti-stick active agent on the inside of the cavity, where it at least partially coats adjacent surfaces.

It is advantageous that the evaporation of the active agent for coating comes about by reduction in pressure of the surrounding atmosphere and/or by an increase in temperature. These conditions favor the evaporating of the active agent and the coating onto the MEMS wafer.

One example embodiment of the method of the present invention provides that the active agent is added to the sealing glass paste. Thereby no special coating step is required for the cap wafer. It is also of advantage that the active agent is added to the atmosphere of an oven while the cap wafer is undergoing a sealing glass pre-bake process in it. The active agent contained in the atmosphere coats the cap wafer during the process.

Another example embodiment of the method according to the present invention provides doping the atmosphere within the closed chamber, especially of the oven, with the active agent, by impregnating a porous element, e.g., one consisting of silicone rubber or phenylsilicone rubber with the active agent, and accommodating the saturated element at a location in the chamber that is at a temperature of 200 to 300° C., e.g., in the supply tube of a gas flushing system. The oven flush gas takes up the active agent and introduces it into the closed chamber. One additional example embodiment provides doping the atmosphere inside the closed chamber with the active agent, by accommodating within the chamber an evaporator source made up of a storage vessel filled with the active agent. It is likewise advantageous to dope the atmosphere within the closed chamber with the active agent, in that the flush gas introduced into the chamber is first doped with the active agent, and especially in that the flush gas is displaced from the evaporator together with the active agent, or in that the flush gas bubbles through the active agent in a bubble vessel. In addition, it is advantageous to dope the atmosphere within the closed chamber with the active agent by evaporating the active agent from a storage flask through a valve via a heated supply line, and introducing it into the closed chamber.

An additional example embodiment of the method provides that the cap wafer and/or the sealing glass is coated with the active agent after the sealing glass pre-bake process. This may be done, for instance, by dispensing, spraying, dipping, doctor blading, silk-screening, CVD coating, rolling or painting. Here it is advantageous that the anti-stick active agent is applied directly before bonding, and is, for example, not able to volatilize during the pre-bake process.

For the coating method according to the present invention, an active agent from the compound class of the silanes may be used. Active agents from this compound class are well suited for the coating, and have particularly good anti-stick properties.

The present invention also relates to a device made up of a micromechanical functional part and a cap connected to it, the micromechanical functional part and the cap enclosing a common cavity.

The present invention provides that at least parts of the surfaces of the functional part and of the cap, which border on the cavity, e.g., the surfaces at which the adhesion described at the outset is able to take place, have an anti-stick coating.

This prevents the adhesion of the micromechanical structures of the functional part among themselves, to the substrate and to the cap. It is possible to use particularly flat caps which extend over the micromechanical structure at a low height. Thereby, in turn, smaller designs of the microelectromechanical components are made possible.

### BRIEF DESCRIPTION OF THE DRAWINGS

FIG. 1 shows a cross-sectional view of an MEMS component having a cap.

FIG. 2 illustrates the method of silk-screening sealing glass onto a cap wafer.

FIG. 3 shows the pre-bake process of a cap wafer having sealing glass printed on it.

FIG. 4 shows the bonding of MEMS wafer and cap wafer.

FIG. 5 shows a liquid source (bubbling vessel) having a tempering jacket.

FIG. 6 shows an evaporating flask having a tempering jacket.

FIG. 7 shows a storage vessel having a perforated lid as an evaporator.

FIG. 8 shows an oven having a storage flask and heated supply.

FIG. 9 shows an evaporator source in the form of a porous element made of silicone rubber in the supply line of flush gas.

FIG. 10 shows a cross-sectional view of a device according to the present invention.

### DETAILED DESCRIPTION

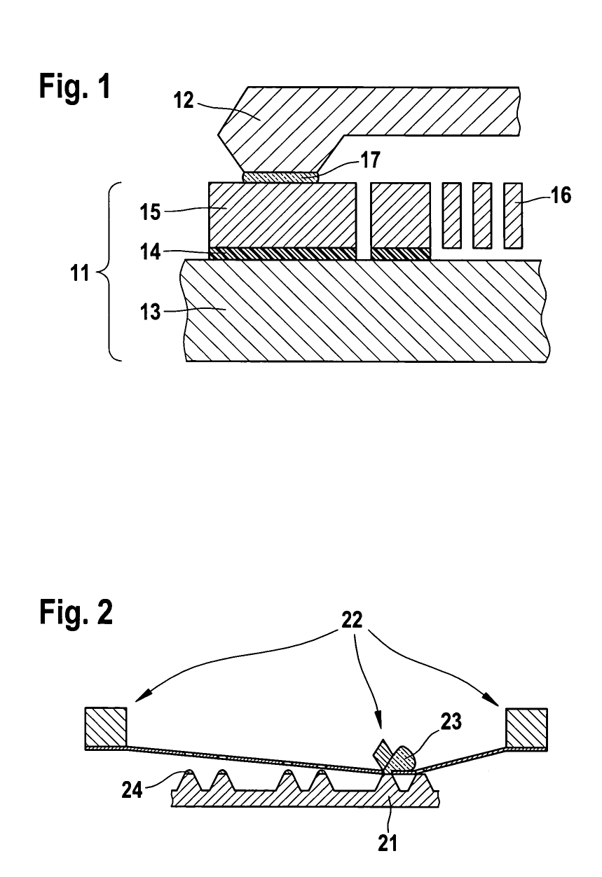

FIG. 1 shows an MEMS component 11 having a cap 12. MEMS component 11 is made up of a first layer or substrate 13, an insulating layer or sacrificial layer 14 and a second layer of functional layer 15 having patterned-out micromechanical elements 16. MEMS component 11 and cap 12 are bonded by a sealing glass 17.

FIG. 2 shows the method of silk-screening sealing glass 23 onto a cap wafer 21. In one embodiment of the present invention, sealing glass 23 is applied to the edges of a cap wafer 21 with the aid of a silk-screeing system 22. The suitable layer thickness of sealing glass coating 24 applied, of, typically, 5 to 40 μm, is achieved by having one or several printing processes. According to one embodiment of the method according to the present invention, sealing glass 23 contains the anti-stick active agent.

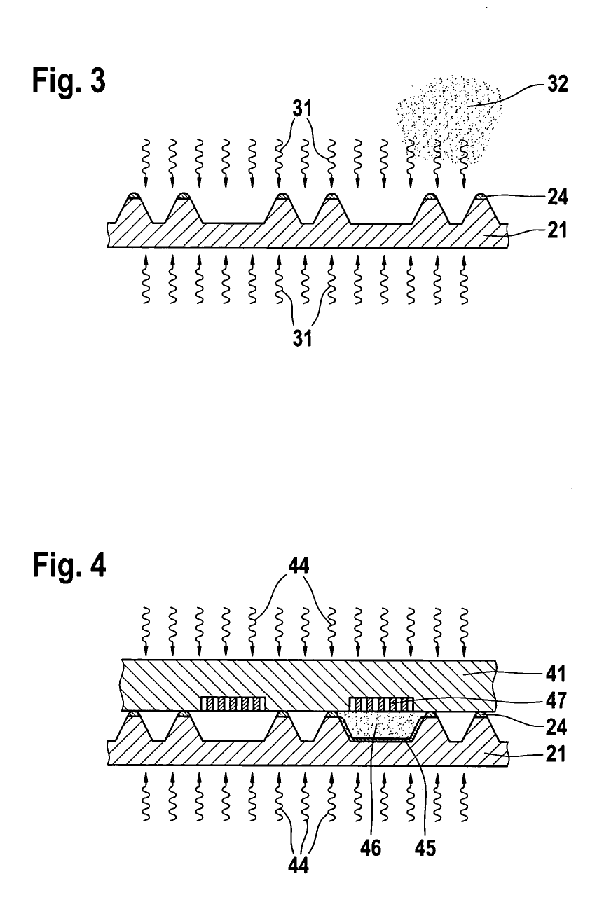

FIG. 3 shows the pre-bake process of a cap wafer 21 provided with sealing glass coating 24. In this context, the organic components of the sealing glass paste are evaporated or burnt off in view of a heating effect 31 at a temperature of ca 300 to 500° C. In addition, depending on the type of glass, a preglassing may take place. According to a further embodiment of the method according to the present invention, atmosphere 32 that surrounds cap wafer 21 is doped with the anti-stick active agent, and the surface of cap wafer 21 is coated with this active agent.

FIG. 4 shows the bonding of MEMS wafer 41 and cap wafer 21. This process step takes place with heating effect 44. In this context, the temperature is selected so that the sealing glass in coating 24 is present in the liquid phase. Typically, temperatures are 300 to 600° C. In this context, MEMS wafer 41 and cap wafer 21 are brought into contact with each other. According to one embodiment of the method according to the present invention, the anti-stick active agent contained in sealing glass coating 24 evaporates and dopes atmosphere 46 enclosed by MEMS wafer 41 and cap wafer 21. The anti-stick active agent settles out from doped atmosphere 46 and coats adjoining surfaces, especially also micromechanical structure 47 of MEMS wafer 41.

According to one additional embodiment of the method according to the present invention, cap wafer and/or sealing glass is/are coated with the anti-stick active agent, especially by dispensing, spraying, dipping, doctor blading, silk-screening, coating from the gas phase (CVD), rolling or painting, after the sealing glass prebake process. This anti-stick active agent applied to the surface of cap wafer 21 now evaporates, during the bonding, from coating 45, and, in turn, dopes the atmosphere in cavity 46 that is enclosed by MEMS wafer 41 and cap wafer 21. The anti-stick active agent deposits from the doped atmosphere and coats adjacent surfaces, especially also micromechanical structure 47 of MEMS wafer 41.

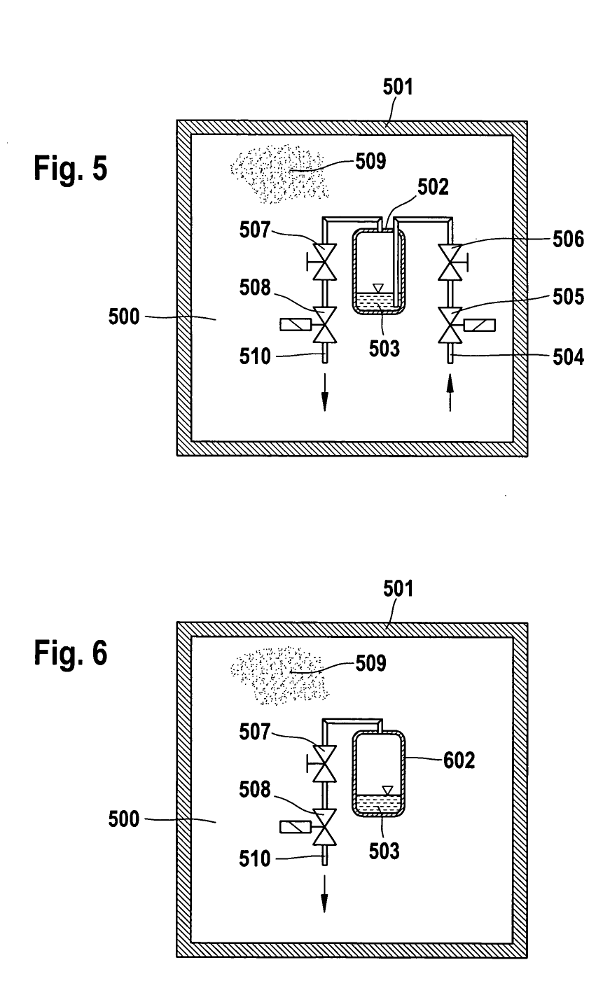

FIG. 5 shows a chamber 500 which is able to be heated by wall 501. According to one embodiment of the method according to the present invention, a liquid source (bubbling vessel) 502 is located in chamber 500, filled with anti-stick active agent 503 in the liquid phase or in a solution of the active agent in an inert solvent. Liquid source 502 has a flush gas supply line 504, especially having a cutoff valve 505 and a control valve 506. In addition, liquid source 502 has a flush gas exit line 510, especially having a cutoff valve 508 and a control valve 507. The oven flush gas flows (bubbles) through supply line 504 into bubble vessel 502, crosses liquid 503, and is, in this context, doped with the anti-stick active agent. The oven flush gas thus doped leaves container 502 through exit line 510, passing control valve 507 and cutoff valve 508, and flows into chamber 500. Atmosphere 509 in chamber 500 is thereby doped with the anti-stick active agent.

FIG. 6 shows a chamber 500 which is able to be heated by wall 501. According to one embodiment of the method according to the present invention, a liquid source (bubbling vessel) 500 is located in chamber 602, filled with anti-stick active agent 503 in the liquid phase or in a solution of the active agent in an inert solvent. Evaporator 602 has an exit line 510, especially having a cutoff valve 508 and a control valve 507. Anti-stick active agent 503 goes over into the gaseous phase in evaporator 602, leaves container 602 through exit line 510, passing through control valve 507 and cutoff valve 508, and flows into chamber 500. Atmosphere 509 in chamber 500 is thereby doped with the anti-stick active agent.

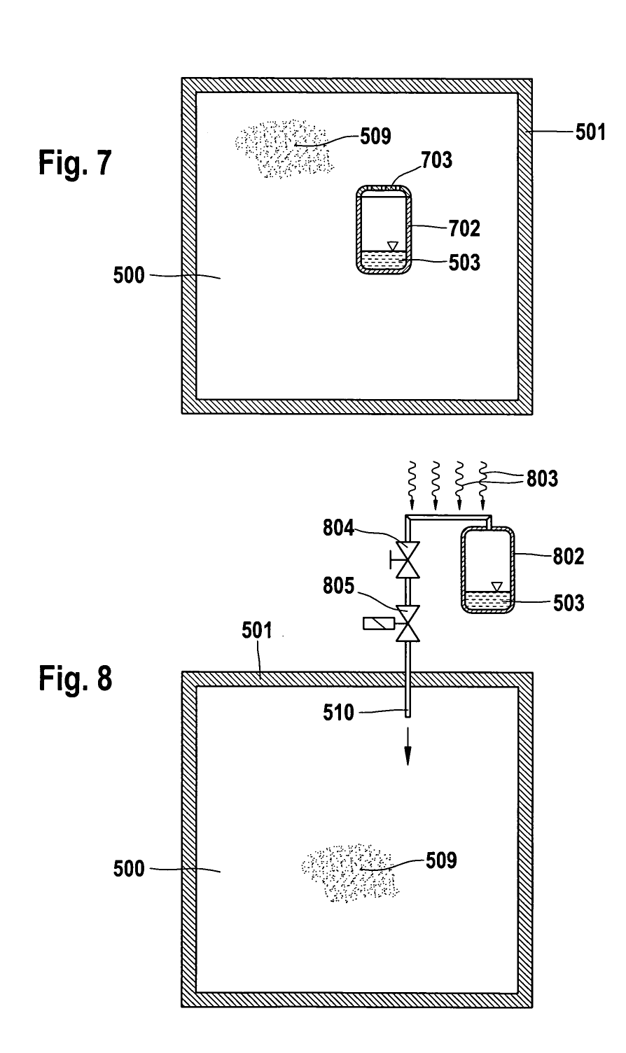

FIG. 7 shows a chamber 500 which is able to be heated by wall 501. According to yet another embodiment of the method according to the present invention, in chamber 500 there is an evaporator in the form of a vessel 702 that has a perforated lid 703. Vessel 702 is filled with anti-stick active agent 503 in the liquid phase, or a solution of the active agent in an inert solvent. Anti-stick active agent 503 is evaporated, i.e., goes over into the gaseous phase in vessel 702, leaves it through perforated lid 703 and flows into chamber 500. Atmosphere 509 in chamber 500 is thereby doped with the anti-stick active agent.

FIG. 8 shows a chamber 500 which is able to be heated by wall 501. According to one further embodiment of the method according to the present invention, outside chamber 500 there is a storage flask 802. Storage flask 802 has a heated exit line 803, especially having a control valve 804, a cutoff valve 805 and an exit 510. Storage flask 802 is filled with anti-stick active agent 503 in the liquid phase or with a solution of the active agent in an inert solvent. Anti-stick active agent 503 is evaporated, leaves storage flask 802 through heated exit line 803 and flows into chamber 500. Atmosphere 509 in chamber 500 is thereby doped with the anti-stick active agent.

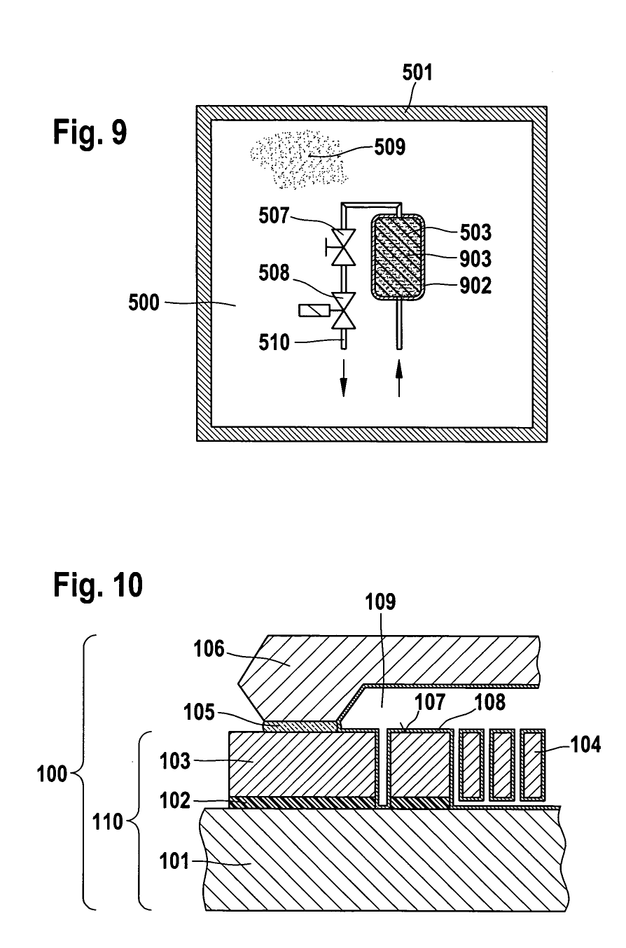

FIG. 9 shows a chamber 500 which is able to be heated by wall 501. According to still another embodiment of the method according to the present invention, in chamber 500 there is located a supply line of a flush gas 902, e.g., at a location in chamber 500 that is heated to ca 200 to 300° C. In supply line 902 a porous element 903, e.g., made of silicone rubber or phenylmethylsilicone rubber, is provided. Element 903 is saturated with anti-stick active agent 503 in the liquid phase or with a solution of the active agent in an inert solvent. Anti-stick active agent 503 evaporates from porous element 903. An oven flush gas is conducted through supply line 902 and thereby becomes doped with anti-stick active agent 503. The flush gas passes a control valve 507 and a cutoff valve 508 and thereafter exits through opening 510 into atmosphere 509 of chamber 500. Atmosphere 509 is thereby doped with the anti-stick active agent.

FIG. 10 shows a device 100 according to the present invention, including functional part 110 and cap 106. Functional part 110 and cap 106 are connected with the aid of sealing glass 105, i.e., they are bonded. Functional part 110 and cap 106 enclose a common chamber. Surfaces 107 bordering on this common chamber are provided with a coating 108 made of an anti-stick active agent. Functional part 110 especially has a substrate 101 and a sacrificial layer 102, on which there is a functional layer 103. The functional layer forms a micromechanical structure 104, which is particularly provided to be movable. Coated surface 107 having coating 108 of device 100 now brings about the fact that, upon contact of one part of movable micromechanical structure 104 with another part, or rather with substrate 101 or with cap 106, no adhesion occurs.

Materials having a vapor pressure>1 mbar at 200° C. are suitable for doping the oven atmosphere, especially according to the methods shown in FIGS. 3-9. Materials having a vapor pressure<1 mbar at 200° C. are suitable for doping the sealing glass, especially according to FIG. 2.

The following groups of silanes are suitable for the anti-stick layers described:

1. Grouping of Silanes Suitable for Anti-Stick Layers for MEMS

1.1 R—SiX3 and Derivatives

R—SiX3 with X=fluorine, chlorine, bromine, methoxy, ethoxy, isopropoxy, alkoxy, acetoxy
R—Si(X)2Me with X as above and Me=methyl
R—Si(X)Me2 with X as above and Me2=dimethyl
R=Rf-Rb with Rf=perfluoroethyl, perfluorobutyl, perfluorohexyl, perfluorooctyl, perfluorodecyl, perfluoromethyl, and Rb=ethyl and methyl, such as, for instance, 1,1,2,2 tetrahydroperfluorooctyl- or 3,3,3 trifluoropropyl
R=alkyl C1 to C30, isopropyl-, t-butyl
R=alkyl 1 to C4 monochlorinated or monoalkoxyalkyl
R=arylalkyl/aryl=phenylethyl-, naphthyl-, 2-methyl-2-phenylethyl, 4-phenylbutyl, pentafluorophenyl, phenyl, phenethyl
R=perfluoropolyether group
R=allyl or 3-acryloxypropyl, aminopropyl, methacryloxymethyl, vinyl
   1.2 R2—SiX2 and Derivatives
with X=fluorine, chlorine, bromine, methoxy, ethoxy, isopropoxy, alkoxy, acetoxy
R=Rf-Rb with Rf=perfluoroethyl, perfluorobutyl, perfluoromethyl and Rb=ethyl and methyl, e.g. 3,3,3-trifluoropropyl
R=arylalkyl/aryl=phenylethyl-, naphthyl-, pentafluorophenyl-, phenyl
R=alkyl C1 to C4, isopropyl-, t-butyl, isobutyl
   1.3 R3—SiX and Derivatives
with X=fluorine, chlorine, bromine, methoxy, ethoxy, isopropoxy, alkoxy, acetoxy
R=Rf-Rb with Rf=perfluoroethyl, perfluorobutyl, perfluoromethyl and Rb=ethyl and methyl, e.g. 3,3,3-trifluoropropyl
R=alkyl C1 to C4, isopropyl
R=arylalkyl/aryl=phenyl
   1.4 X3Si-Rc-SiX3 and Derivatives
X3Si-Rc-SiX3 with X as above and Rc=methyl, ethyl, propyl, butyl, bifunctional perfluoropolyethers
(X)2Me Si-Rc-Si(X)2Me with X and Rc as above
(X)Me2Si-Rc-Si(X)Me2 with X and Rc as above
   1.5 Polymers
poly(borondiphenylsiloxane)
copolymers of diphenyl and dimethylsiloxane, e.g. trimethyl pentaphenyltrisiloxane DC705, tetramethyltetraphenyltrisiloxane DC704
   1.6 Cyclic Silanes
1,1,3,3,5,5 hexamethylcyclotrisilazane,
1,3-dimethyl-1,1,3,3-tetraphenyldisilazane,
1,3-diphenyl-1,1,3,3-tetramethyldisilazane,
octamethylcyclotetrasilazane,
octaohenylcyclotetrasiloxane
   1.7 Suitable Silazanes and Siloxanes
1,3-divinyltetramethyldisilazane,
hexamethyldisilazane,
hexamethyldisiloxane,
octaphenyltetrasilazane,
octaphenyltetrasiloxane
   1.8 Derivatization Means for Gas Chromatography
N-(trimethylsilyl)dimethylamine,
N,N-bis(trimethylsilyl)methylamine,
N,O-bis(trimethylsilyl)acetamide,
N,O-bis(trimethylsilyl)carbamate,
N,O-bis(trimethylsilyl)trifluoroacetamide,
N-butylaminopropyltrimethoxysilane,
N-methyl-N-trimethylsilyltrifluoroacetamide.

In addition, the following commercially available silanes are suitable for anti-stick coatings of MEMS components:
reactive perfluoropolyether derivatives, such as alkoxysilane-terminated PFPE's 7007x or Galden MF 400 series, phosphoric acid-terminated PFPE's Galden MF 201 or MF 200 series, Galden MF 407 (perfluoropolyether having amidosilane end groups), Fomblin Fluorolink S, all from the firm Ausimont, Bollate, Italy,
poly(borondiphenylsiloxane), e.g., type SSP040, from the firm of Gelest,
oils composed of copolymers of diphenyl and dimethyl siloxane, e.g., types PDM-0421, PMM-1043, PMP-5053, PDM-7040, PDM 7050, from the firm of Gelest, or the types from the AP- or AS-series of the firm Wacker Burghausen, such as AP 150.

Finally, there follows an alphabetical list of the suitable silanes identified up to the present for anti-stick coatings of mems components:
(2-methyl-2-phenylethyl)methyldichloro silane,
(3-acryloxypropyl)trimethoxysilane,
1,1,2,2-tetrahydroperfluorodecyltriethoxysilane,
1,1,3,3,5,5 hexamethylcyclotrisilazane,
1,2-bis(chlorodimethylsilyl)ethane,
1,3-bis(chlorodimethylsilyl)butane,
1,3-bis(chlorodimethylsilyl)propane,
1,3-bis(dichlorodimethylsilyl)propane,
1,3-bis(trichlorosilyl)propane,
1,3-dimethyl-1,1,3,3-tetraphenyldisilazane,
1,3-diphenyl-1,1,3,3-tetramethyldisilazane,
1,3-divinyltetramethyldisilazane,
11-(chlorodimethylsilylmethyl)-heptacosane,
11-(dichlorodimethylsilylmethyl)-heptacosane,
11-(trichlorosilylmethyl)-heptacosane,
13-(chlorodimethylsilylmethyl)-heptacosane,
13-(dichloromethylsilylmethyl)-heptacosane,
13-(trichlorosilylmethyl)-heptacosane,
2-chloroethyltrichlorosilane,
3-chloropropyltrichlorosilane,
3-chloropropyltrimethoxysilane,
di(3,3,3-trifluoropropyl)dichlorosilane,
3,3,3-trifluoropropyltriacetoxysilane,
3,3,3-trifluoropropyltribromosilane,
3,3,3-trifluoropropyltrichlorosilane,
3,3,3-trifluoropropyltriethoxysilane,
3,3,3-trifluoropropyltrifluorosilane,
3,3,3-trifluoropropyltriisopropoxysilane,
3,3,3-trifluoropropyltrimethoxysilane,
3-methoxypropyltrimethoxysilane,
4-phenylbutyldimethylchlorosilane,
4-phenylbutylmethyldichlorosilane,
4-phenylbutylmethyldimethoxysilane,
4-phenylbutyltrichlorosilane,
4-phenylbutyltriethoxysilane,
4-phenylbutyltrimethoxysilane,
acetoxypropyltrimethoxysilane,
allyloxyundecyltrimethoxysilane,
allyltrichlorosilane,
aminopropyltriethoxysilane,
aminopropyltrimethoxysilane,
Ausimont Fomblin Fluorolink s,
Ausimont Galden 7007x 8-perfluoropolyether with alkoxysilane end groups),
Ausimont Galden MF 407 (perfluoropolyether with amidosilane end groups),
di(3,3,3-trifluoropropyl)diacetoxysilane,
di(3,3,3-trifluoropropyl)dibromosilane,
di(3,3,3-trifluoropropyl)dichlorosilane,
di(3,3,3-trifluoropropyl)diethoxysilane,
di(3,3,3-trifluoropropyl)difluorosilane,
di(3,3,3-trifluoropropyl)diisopropoxysilane,
di(3,3,3-trifluoropropyl)dimethoxysilane,
di(pentafluorophenyl)diacetoxysilane,
di(pentafluorophenyl)dibromosilane,
di(pentafluorophenyl)dichlorosilane,
di(pentafluorophenyl)diethoxysilane,
di(pentafluorophenyl)difluorosilane,
di(pentafluorophenyl)diisopropoxysilane,
di(pentafluorophenyl)dimethoxysilane,
diethyldiacetoxysilane,
diethyldibromosilane,
diethyldichlorosilane,
diethyldiethoxysilane,
diethyldifluorosilane,
diethyldiidopropoxysilane,
diethyldimethoxysilane,
diisopropyldiacetoxysilane,
diisopropyldibromosilane,
diisopropyldichlorosilane,
diisopropyldiethoxysilane,
diisopropyldifluorosilane,
diisopropyldiisopropoxysilane,
diisopropyldimethoxysilane,
dimethylchlorosilane,
dimethyldiacetoxysilane,
dimethyldibromosilane,
dimethyldichlorosilane,
dimethyldiethoxysilane,
dimethyldifluorosilane,
dimethyldiisopropoxysilane,
dimethyldimethoxysilane,
dimethylethoxysilane,
dimethylmethoxysilane,
dimethyllhenylchlorosilane,
di-n-butyldichlorosilane,
di-n-butyldiethoxysilane,
di-n-butyldimethoxysilane,
diphenyldiacetoxysilane,
diphenyldibromosilane,
diphenyldichlorosilane,
diphenyldiethoxysilane,
diphenyldifluorosilane,
diphenyldiisopropoxysilane,
diphenyldimethoxysilane,
diphenylmethylchlorosilane,
diphenylsilanediol,
dipropyldiacetoxysilane,
dipropyldibromosilane,
dipropyldichlorosilane,
dipropyldiethoxysilane,
dipropyldifluorosilane,
dipropyldiisopropoxysilane,
dipropyldimethoxysilane,
di-t-butyldichlorosilane,
docosenyltriethoxysilane,
dodecyltrichlorosilane,
dodecyltriacetoxysilane,
dodecyltriethoxysilane,
dodecyltrimethoxysilane,
ethylphenethyltrimethoxysilane,
ethyltriacetoxysilane,
ethyltribromosilane,
ethyltriethoxysilane,
ethyltrifluorosilane,
ethyltriisopropoxysilane,
ethyltrimethoxysilane,
hexadecyltrichlorosilane,
hexamethyldisilazane,
hexamethyldisiloxane,
isobutyltrimethoxysilane,
isopropyltriacetoxysilane,
isopropyltribromosilane,
isopropyltrichlorosilane,
isopropyltriethoxysilane,
isopropyltrifluorosilane,
isopropyltriisopropoxysilane,
isopropyltrimethoxysilane,
methacryloxymethyltriethoxysilane,
methacryloxymethyltrimethoxysilane,
methyltriacetoxysilane,
methyltribromosilane,
methyltriethoxysilane,
methyltrifluorosilane,
methyltriisopropoxysilane,
methyl trimethoxysilane,
n-(trimethylsilyl)dimethylamine,
n,n-bis(trimethylsilyl)methylamine,
n,o-bis(trimethylsilyl)acetamide,
n,o-bis(trimethylsilyl)carbamate,
n,o-bis(trimethylsilyl)trifluoroacetamide,
naphthyltriacetoxysilane,
naphthyltribromosilane,
naphthyltrichlorosilane
naphthyltriethoxysilane,
naphthyltrifluorosilane,
naphthyltriisopropoxysilane,
naphthyltrimethoxysilane,
n-butylaminopropyltrimethoxysilane,
n-methyl-n-trimethylsilyltrifluoroacetamide,
n-octadecyltrichlorosilane,
n-undecyltrichlorosilane,
octadecyldimethylchlorosilane,
octadecyltrichlorosilane,
octadecyltriethoxysilane,
octadecyltrimethoxysilane,
octamethylcyclotetrasilazane,
octaohenylcyclotetrasiloxane,
octaphenyltetrasilazane,
octaphenyltetrasiloxane,
octylmethyldichlorosilane,
octylmethyldimethoxysilane,
octyltrichlorosilane,
octyltriethoxysilane,
octyltrimethoxysilane,
pentafluorophenylacetoxysilane,
pentafluorophenyldimethylchlorosilane,
pentafluorophenylmethyldichlorosilane,
pentafluorophenylmethyldimethoxysilane,
pentafluorophenylpropyltrichlorosilane,
pentafluorophenyltriacetoxysilane,
pentafluorophenyltribromosilane,
pentafluorophenyltrichlorosilane,
pentafluorophenyltriethoxysilane,
pentafluorophenyltrifluorosilane,
pentafluorophenyltriisopropoxysilane,
pentafluorophenyltrimethoxysilane,
perfluorodecyl-1H,1H,2H-2H-dimethylchlorosilane,
perfluorodecyl-1H,1H,2H-2H-methyldichlorosilane,
perfluorodecyl-1H,1H,2H-2H-triacetoxysilane,
perfluorodecyl-1H,1H,2H-2H-trichlorosilane,
perfluorodecyl-1H,1H,2H-2H-triethoxysilane,
perfluorodecyl-1H,1H,2H-2H-trimethoxysilane,
perfluorododecyl-1H,1H,2H-2H-dimethylchlorosilane,
perfluorododecyl-1H,1H,2H-2H-methyldichlorosilane,
perfluorododecyl-1H,1H,2H-2H-trichlorosilane,
perfluorododecyl-1H,1H,2H-2H-triethoxysilane,
perfluorododecyl-1H,1H,2H-2H-trimethoxysilane,
perfluorohexyl-1H,1H,2H,2H-dimethylchlorosilane,
perfluorohexyl-1H,1H,2H-2H-methyldichlorosilane,
perfluorohexyl-1H,1H,2H-2H-trichlorosilane,
perfluorohexyl-1H,1H,2H-2H-triethoxysilane,
perfluorohexyl-1H,1H,2H-2H-trimethoxysilane,
perfluorohexyl-1H,1H,2H,2H-dimethylchlorosilane,
perfluorooctyl-1H,1H,2H-2H-methyldichlorosilane,
perfluorooctyl-1H,1H,2H-2H-triacetoxysilane,
perfluorooctyl-1H,1H,2H-2H-trichlorosilane,
perfluorooctyl-1H,1H,2H-2H-triethoxysilane,
perfluorooctyl-1H,1H,2H-2H-trimethoxysilane,
phenethyltrichlorosilane,
phenethyltrimethoxysilane,
phenyltriacetoxysilane,
phenyltribromosilane,
phenyltrichlorosilane,
phenyltriethoxysilane,
phenyltrifluorosilane,
phenyltriisopropoxysilane,
phenyltrimethoxysilane,
propyltriacetoxysilane,
propyltribromosilane,
propyltrichlorosilane,
propyltriethoxysilane,
propyltrifluorosilane,
propyltriisopropoxysilane,
propyltrimethoxysilane,
t-butyldimethylchlorosilane,
t-butyldiphenylchlorosilane,
tetramethyltetraphenyltrisiloxane DC704,
thexyl[sic]dimethylchlorosilane,
tri(3,3,3-trifluoropropyl)acetoxysilane,
tri(3,3,3-trifluoropropyl)bromosilane,
tri(3,3,3-trifluoropropyl)fluorosilane,
tri(3,3,3-trifluoropropyl)chlorosilane,
tri(3,3,3-trifluoropropyl)ethoxysilane,
tri(3,3,3-trifluoropropyl)fluorosilane,
tri(3,3,3-trifluoropropyl)isopropoxysilane
tri(3,3,3-trifluoropropyl)methoxysilane,
triethylacetoxysilane,
triethylbromosilane,
triethylchlorosilane,
triethylethoxysilane,
triethylfluorosilane,
triethylisopropoxysilane,
triethylmethoxysilane,
triisopropylacetoxysilane,
triisopropylbromosilane,
triisopropylchlorosilane,
triisopropylethoxysilane,
triisopropylfluorosilane,
triisopropylisopropoxysilane,
triisopropylmethoxysilane,
trimethylacetoxysilane,
trimethylbromosilane,
trimethylchlorosilane,
trimethylethoxysilane,
trimethylfluorosilane,
trimethyliodosilane,
trimethylisopropoxysilane,
trimethylmethoxysilane,
trimethylpentaphenyltrisiloxane DC705
triphenylchlorosilane,
triphenylmethyldimethylchlorosilane,
triphenylmethylmethyldichlorosilane,
triphenylmethylmethyldimethoxysilane,
triphenylmethyltrichlorosilane,
triphenylmethyltriethoxysilane,
triphenylmethyltrimethoxysilane,
tripropylacetoxysilane,
tripropylbromosilane,
tripropylchlorosilane,
tripropylethoxysilane
tripropylfluorosilane,
tripropylisopropoxysilane,
tripropylmethoxysilane,
undecyldimethylchlorosilane,
undecylmethyldimethoxysilane,
undecyltrichlorosilane,
undecyltriethoxysilane,
undecyltrimethoxysilane,
vinyltriethoxysilane.

1. A method for producing a coating layer having anti-stick properties on a surface of an MEMS wafer, comprising:
applying an active agent for the coating layer to a cap wafer;
connecting the cap wafer to the MEMS wafer, whereby at least one cavity is enclosed between the cap wafer and the MEMS wafer; and
evaporating the active agent at least one of during the connecting step and subsequent to the connecting step, whereby at least parts of the surface of the MEMS wafer are coated by the evaporated active agent.

2. The method as recited in claim 1, wherein the cap wafer is connected to the MEMS wafer using a sealing glass paste.

3. The method as recited in claim 1, wherein the evaporation of the active agent and the coating are achieved by at least one of a reduction in the pressure of the surrounding atmosphere and an increase in the temperature.

4. The method as recited in claim 2, wherein the active agent is added to the sealing glass paste.

5. The method as recited in claim 2, further comprising:
exposing the cap wafer to a sealing glass pre-bake process in a chamber, wherein the active agent is added to the atmosphere of the chamber.

6. The method as recited in claim 5, wherein the atmosphere within the chamber is doped with the active agent, by impregnating a porous element with the active agent, and positioning the porous element at a location in the chamber that is at a temperature of approximately 200 to 300° C.

7. The method as recited in claim 5, wherein the atmosphere within the chamber is doped with the active agent by positioning an evaporator source that includes a storage vessel filled with the active agent, within the chamber, and wherein the active agent is evaporated in the chamber.

8. The method as recited in claim 5, wherein the atmosphere within the chamber is doped with the active agent by first doping a flush gas introduced into the chamber with the active agent, by one of having the flush gas bubble through the active agent in a bubbling vessel and adding the active agent, from an evaporator, to the flush gas.

9. The method as recited in claim 5, wherein the atmosphere is doped with the active agent by evaporating the active agent from a storage bottle through a valve and a heated supply line, and introducing the active agent into the chamber.

10. The method as recited in claim 2, wherein at least one of the cap wafer and the sealing glass is coated at least partially with the active agent by at least one of dispensing, spraying, dipping, doctor blading, silk-screening, coating from the gas phase (CVD), rolling and painting, after a sealing glass pre-bake process.

11. The method as recited in claim 1, wherein the active agent includes at least one compound from the class of compounds of silanes.

12. A device comprising:
a micromechanical functional part; and
a cap firmly connected to the functional part;
wherein the functional part and the cap enclose a common cavity, and wherein at least parts of surfaces of the device that border on the cavity have a non-stick coating.

13. The device as recited in claim 12, wherein all surfaces of the device that border on the cavity have the non-stick coating.

14. The device as recited in claim 12, wherein the atmosphere in the cavity is doped with an active agent for the non-stick coating.

15. The device as recited in claim 12, wherein a sealing glass contains an active agent for the non-stick coating.

16. The device as recited in claim 12, wherein an active agent for the non-stick coating includes at least one compound from the class of compounds of silanes.
